(19) United States
(12) Patent Application Publication
(10) Pub. No.: US 2006/0210766 A1
(43) Pub. Date: Sep. 21, 2006

(54) Enhanced friction treatment for flexible panels and articles made thereby

(75) Inventors: Stuart Press, Gullford, CT (US); Doug Jacot, Kingston, WA (US)

Correspondence Address: GRAYBEAL JACKSON HALEY LLP;Stephen M. Evans, Suite. 350, 155-108th Avenue N.E., Bellevue, WA, 98004-5901, US

(73) Assignee: Cascade Designs, Inc.

(21) Appl. No.: 11/335,164

(22) Filed: Jan. 18, 2006

Related U.S. Application Data
(63) Continuation-in-part of application No. PCT/US04/23165, filed on Jul. 19, 2004.
(60) Provisional application No. 60/488,454, filed on Jul. 18, 2003.

(51) Int. Cl. C23C 16/52; B05D 5/00; B32B 7/00

(52) U.S. Cl. 428/119; 427/256; 427/8

(57) ABSTRACT

A selective material deposition treatment for flexible substrate to increase the coefficient of friction between the flexible substrate and a user, or article worn by the user. The material deposition treatment may rely upon the physical properties of the deposited material, such as the area, shape, density, topology or profile of the material, upon the mechanical properties of the material, or upon combinations thereof to enhance the friction of the substrate. Methods include identifying a pattern having a plurality of elements to be applied to the panel; identifying a desired coating composition to be applied to the substrate; and selectively applying the coating to at least a user contacting side of the substrate to generally recreate the pattern thereon. Uses for articles produced according to the methods include portable mattresses, pads, cushions, tent floors, technical outerwear, friction tape and others.

### CROSS-REFERENCE TO PRIORITY APPLICATION

This is a continuation-in-part application that claims benefit, under 35 USC §120, of co-pending International Application PCT/US04/23165, filed on 19 Jul. 2004, designating the United States, which claims foreign priority benefits under 35 USC §119 (a) to U.S. Provisional Patent Application No. 60/488,454, filed 18 Jul. 2003, which applications are incorporated herein by reference.

### BACKGROUND OF THE INVENTION

High performance backcountry articles, such as camping mattresses/pads and tents, need to be light in weight and compact in size so a backpacker or mountaineer can minimize the weight they must carry. In order to keep the user on a camping pad and the pad stationary on sloped surfaces, it should be constructed of high friction materials on both the top and bottom of the pad. Alternatively, or in addition to this, having a floor of a tent structure that also has low-slip properties is considered desirable: not only do pads stay in place better, but any object placed on the floor will also benefit from such an enhanced friction surface.

Current non-slip, high friction or low-slip fabrics are constructed of high bulking textured yarns. DuPont, Inc. makes appropriate fabrics of this type, under the brand name Supplex®. The loose or random nature of some of the filaments provides enough texture to increase the surface friction of the woven fabric. However, because textured yarn is used on both sides of the mattress/pad surface, weight is increased everywhere. Moreover, the loose yarn does nothing to increase the mechanical strength of the textile. In addition, to make a fluid impervious mattress/pad from textured fabric, a relatively large amount of polymeric coating must be applied to the inside surfaces of the fabric, further increasing weight. In general, the nature of the current art for creating high friction mattress/pad fabric creates the undesirable side effect of increasing the base fabric's weight from 30-60%. This consequence runs contrary to the stated goal of providing a mattress/pad solution having minimal weight properties.

Similar consequences occur with respect to tent floors. The overall weight of a tent is of great concern to backpackers, however, providing a slip-resistant tent floor is also considered highly desirable, given the generally non-level or irregular surfaces upon which the tents are erected.

The need for lightweight, slip-resistant fabrics and similar materials extends beyond those applications described above. Additional applications include technical outerwear such as snow and climbing clothing (bibs, jackets and pants), knee and elbow pads, tablecloths and mats, fabric friction tape (e.g., bicycle handlebar tape) and other applications wherein low weight and increased slip-resistance in a high longevity product are desirable.

### SUMMARY OF THE INVENTION

The invention is directed to a material deposition treatment that can be applied to at least a user contacting side of a flexible substrate to increase the coefficient of friction between the user, or an article worn by the user, and the substrate without appreciably increasing the overall weight of the substrate or a structure incorporating the substrate. The material deposition treatment may rely upon the physical properties of the deposited material, such as the area, shape, density, topology or profile of the material, upon the mechanical properties of the material, or upon combinations thereof to enhance the friction of the substrate. The invention is therefore directed to methods for creating such a material deposition treatment and articles produced thereby.

Methods according to the invention are broadly characterized as selectively applying a friction enhancing coating to a flexible substrate where the selective application comprises a plurality of “elements”, preferably in the form of repeating patterns. The flexible substrate comprises at least one of nylon, polyester, acetate, poly/cotton, aramid, Lycra®, Vectran®, polypropylene, Nomex®, or Spectra®. The coating comprises at least one of acrylics, epoxies, polyvinyl chlorides, polyolifins, neoprenes, polyurethanes, butyls, Hypalon®, nitrites, Viton®, polyethylenes, polypropylenes, polystyrenes or silicones, all of which may include the incorporation of silica and/or any aggregates. The methods for applying the coating to the substrate comprises planar screening, rotary screening, reverse rolling, direct spraying, transfer coating or rotogravure transferring.

In a preferred method, rotogravure printing is used due to its ability to deposit polymeric elements with highly raised profiles (the height above the substrate being coated). A cross-linked polyurethane compound is a preferred coating due to its adhesive ability, durability, acceptability of pigments, and easily controlled viscosity, amongst other properties.

The product resulting from practicing the methods of the invention is a durable and lightweight article incorporating a plurality of “elements” (raised geometric shapes) corresponding to the template used during the material deposition process. Depending upon the mode of material deposition, the template can be a physical item such as a screen or drum, or can be data such as used with a CNC direct spraying apparatus. Thus, a treatment creating a plurality of raised geometric shapes that cover 25% of a textile's outer surface area can result in an article having increase of overall weight of less than 10%. Applying the right polymer to a typical coated nylon taffeta fabric used in self-inflating mattresses will yield a product that has a 30%-40% reduction in the weight compared to the previous state-of-the-art non-slip fabrics, and is significantly lighter than any textured mattress fabrics currently available.

A preferred process for applying the raised geometric shapes to a woven fabric material used in self-inflating mattresses uses a hot melt rotogravure line applying a plurality of cross-linked polyurethane “elements” to one side of a nylon taffeta fabric. The pattern of the gravure roll is infinitely variable so those patterns can be matched to different substrates, although in this embodiment the pattern comprises spaced-apart truncated domes. Additionally, it is found that the height or profile of the shapes is important to maximizing friction with the least amount of added weight. Moreover, the polyurethane should be sufficiently cross-linked so that the pattern is retained during a mattress manufacturing process such as is described, for example, in U.S. Pat. No. 4,025,974, which is incorporated herein by reference. Cross-linking also provides abrasion resistance and durability. As noted above, additives and pigments can be added to the base coating for color as well as to increase friction.

It will be appreciated that articles resulting from the processes described herein have a plurality of variables, all of which may be modified to produce a desired result. With respect to the selective application of a coating, each “element” has three primary properties that affect its contribution to the increased coefficient of friction possessed by the treated substrate: the element footprint (i.e., the two dimensional area of the element at the coating-substrate interface), the element height (e.g., topology and cross sectional profile considerations), and the element composition.

### BRIEF DESCRIPTION OF THE DRAWINGS

FIG. 1 is a perspective view a flexible substrate having a plurality of friction enhancing elements in the form of truncated domes deposited thereon;

FIG. 2 is a plan view of the embodiment of FIG. 1;

FIG. 3 is an elevation view of the embodiment of FIG. 1;

FIG. 4 a footprint of the truncated dome shown in FIGS. 1-3;

FIG. 5 is a partial footprint of a linear element;

FIG. 6 is a partial footprint of a stepped or “zig-zag” linear element;

FIG. 7 is a footprint of an elliptical element;

FIG. 8 is a footprint of a triangular element;

FIG. 9 is a footprint of a square element;

FIG. 10 is a footprint of a four-armed element;

FIG. 11 is a partial footprint of a waffle pattern element that can be conceptualized as comprised of connected four-armed elements;

FIG. 12 is a perspective view of a five-armed “starfish” element showing a central protrusion and spines or ridges on each arm;

FIG. 13 is a perspective view of a six-armed “starfish” element showing a central elevated depression and spines or ridges on each arm;

FIG. 14 is a cross section view of a dome element;

FIG. 15 is a cross section view of a dome element having a central protrusion;

FIG. 16; is a cross section view of a dome element having a central protrusion defining a central depression

FIG. 17; is a cross section perspective view of an elongate linear element having a pair of longitudinal parallel ridges

FIG. 18; is a cross section view of a cone or pyramidal element; and

FIG. 19 is a cross section perspective view of an elongate linear element having a pair of longitudinal parallel ridges.

### DETAILED DESCRIPTION OF THE SEVERAL EMBODIMENTS

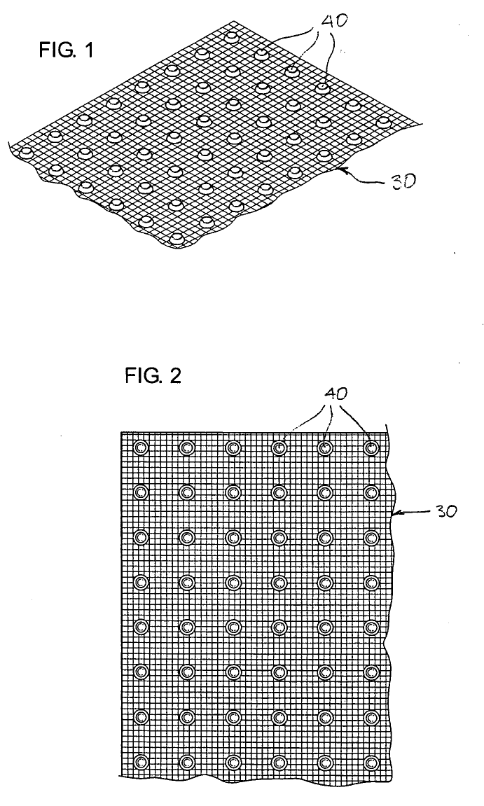

Turning then to the several figures, wherein like numerals indicate like parts, and more particularly to FIGS. 1-3, a first embodiment of the invention is shown. In this first embodiment, panel 30 is shown with a plurality of friction enhancing elements 40 fixedly adhered thereto. Panel 30 is a nylon taffeta fabric, having no special characteristics, i.e., no special intrinsic properties such as brushed thread. Each element 40 is preferably formed from a cross-linked polyurethane compound, and has been applied to panel 30 using a rotogravure deposition process. In the illustrated embodiment, the elements are characterized as generally truncated domes having a base diameter of about 25 mils (0.635 mm) and a height of about 5 mils (0.127 mm).

The field density of elements 40 is generally driven by an enhanced friction factor versus an increased weight factor. Variables to be addressed include the weight density of the coating compound and the volume of each element. Thus, the field density range can be from as little as 5% of the available panel area to as much as 90%. Moreover, each element can be minimized if a large number is used, or can be maximized if few elements are used to achieve the desired enhancement versus weight combination. If dome-shaped elements are used, preferably densities range from about 187 elements per square inch (29 elements per square centimeter) to about 382 elements per square inch (59 elements per square centimeter). In addition, each element can be compact, such as a dome, or elongate, such as a line (linear or otherwise).

FIGS. 4-11 illustrate a variety of elements having unique “footprints”. In addition to element density and size, the geometric shape of an element affects the overall performance of a treated panel. An element may comprise simple geometric forms, such as in FIGS. 4, and 7-10; it may comprise the integration of a plurality of elements, such as shown in FIG. 11; or it may be a many armed geometric form, such as shown in FIGS. 10, 12, and 13.

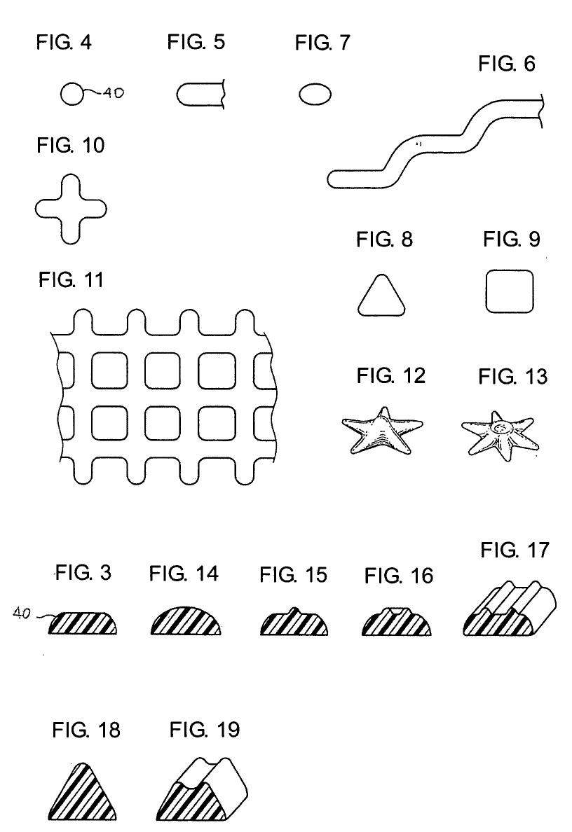

Also affecting friction performance is the elevation profile and topology of each element. FIGS. 3, 12, 13 and 14-19 illustrate a variety of element profiles in cross-section and perspective, with particular emphasis on the apex of each element. FIG. 3 shows a truncated dome feature for element 40. This geometry has been found particularly effective for enhancing friction against generally planar surfaces. FIGS. 14-19 shows various embodiments having an apex, which has been found effective for enhancing friction against resilient surfaces, e.g., soft surfaces. In FIGS. 15 and 18, there is a single pointed apex, a similar version also appearing in FIG. 12 in conjunction with ridges extending along radial arms; in FIG. 16 the apex is characterized as elevated divot, a similar version also appearing in FIG. 13 in conjunction with ridges extending along radial arms.

Thus, it should be understood that any given element can possess each form of apex exclusively or in combination. Logically, any given element can also possess a plurality of apexes, in addition to other structure, as is illustrated in FIGS. 17 and 19. Moreover, the apex(es) of each element need not converge to a point, but may converge to form a linear apex or ridge such as shown in FIGS. 12 and 13. Again, various combinations of these manifestations can be employed in a single element, or a heterogeneous combination thereof, employed to form the overall pattern. Each element footprint, its elevation profile, its topology, its combination into a pattern, the density of the pattern, and the element composition all are factors in determining a desirable construction of a coated flexible panel.

Of particular applicability of element 40 is with respect to inflatable mattresses or pads. In these articles, a resilient material is sandwiched between two flexible panels where the resilient material is substantially bonded to the inside surfaces of the panels, and the panel perimeters are sealed to one another, thereby establishing a fluid impervious chamber. A valve is established between the chamber and the environment to regulate the influx and efflux of air into and from the chamber. At least one panel outer surface is treated according to the treatment methods described herein to create a friction enhanced inflatable mattress or pad. The treatment may take place prior to the construction of the mattress or pad, or may take place thereafter.

What is claimed:

1. A method for enhancing the overall coefficient of friction for a flexible substrate having at least a user contacting side comprising:
a) identifying a pattern having a plurality of elements to be applied to the flexible substrate;
b) identifying a desired coating composition to be applied to the flexible substrate; and
c) selectively applying the coating composition to at least the user contacting side of the substrate to generally recreate the pattern on the substrate.

2. The method of claim 1, wherein the pattern comprises a plurality of elements having similar height and area characteristics.

3. The method of claim 1, wherein the pattern covers substantially between 3% and 90% of the substrate.

4. The method of claim 1, wherein the pattern covers substantially between 5% and 20% of the substrate.

5. The method of claim 1, wherein the pattern comprises ordered elements.

6. The method of claim 1, wherein the pattern comprises disordered or random elements.

7. The method of claim 1, wherein the pattern comprises a plurality of symmetrically aligned elements.

8. The method of claim 1, wherein the pattern comprises a plurality of asymmetrical aligned elements.

9. The method of claim 1, wherein the pattern comprises a plurality of truncated geometric elements such that a substantially planar surface is at an upper portion of each of the plurality of elements.

10. The method of claim 1, wherein the pattern comprises a plurality of generally circular domes.

11. The method of claim 10, wherein the domes are truncated such that a substantially planar surface is at an upper portion of each of the plurality of generally circular domes.

12. The method of claim 1, wherein the pattern comprises elements, at least some having an apex.

13. The method of claim 1, wherein the pattern comprises elements, at least some having a linear ridge.

14. The method of claim 1, wherein the pattern comprises elements having arms.

15. The method of claim 1, wherein the pattern comprises elongate elements having a major axis and a minor axis wherein the major axis is at least three times that of the minor axis.

16. The method of claim 1, wherein the pattern comprises an integration of at least one geometric shape.

17. The method of claim 1, wherein the pattern comprises at least one linear element.

18. The method of claim 17, wherein the at least one linear element forms a zig-zag.

19. The method of claim 1, wherein the pattern comprises elements characterized as annular wherein the substrate is exposed in the middle of the annulus.

20. The method of claim 1, wherein the coating composition is at least one of an acrylic, an epoxy, a polyvinyl chloride, a polyolifin, a neoprene, a polyurethane, a butyl, Hypalon®, a nitrile, Viton®, a polyethylene, a polypropylene, a polystyrene or a silicone.

21. The method of claim 20 wherein the coating composition further comprises the incorporation of an adjunct comprising a silica.

22. The method of claim 1, wherein the substrate is one of a nylon, a polyester, an acetate, a poly/cotton blend, an aramid, Lycra®, Vectran®, a polypropylene, Nomex®, or Spectra®.

22. The method of claim 1, wherein the selective application of the coating uses one of planar screening, rotary screening, reverse rolling, direct spraying, transfer coating or rotogravure transferring.

23. The method of claim 1, wherein the substrate comprises a fluid impervious coating on a side opposite the user contacting side.

24. A pad comprising:
a first flexible panel having an inner surface and an outer surface;
a second flexible panel opposed to and spaced apart from the first flexible panel, and having an inner surface and an outer surface
wherein at least the outer surface of one flexible panel comprises a plurality of selectively applied friction enhancing elements bonded to and extending away from the outer surface.

25. A temporary shelter having a plurality of flexible panels including a floor portion having a user contacting surface, and comprising:
a friction enhanced coating wherein the coating comprises a plurality of friction enhancing elements selectively bonded to and extending away from the user contacting surface.
